(19) United States
(12) Patent Application Publication
(10) Pub. No.: US 2011/0171426 A1
(43) Pub. Date: Jul. 14, 2011

(54) HARD WATER-REPELLENT STRUCTURE AND METHOD FOR MAKING THE SAME

(75) Inventors: Chih-Wei Chen, Hsinchu Hsieh (TW); Chun-Hung Lin, Hsinchu Hsieh (TW); Tsung-Hui Cheng, Hsinchu Hsieh (TW); Chih-Yuan Chen, Hsinchu Hsieh (TW); Te-Hui Yang, Hsinchu Hsieh (TW); Chen-Der Tsai, Hsinchu Hsieh (TW); Chin-Jyi Wu, Hsinchu Hsieh (TW); Yun-Chuan Tu, Hsinchu Hsieh (TW); Chia-Chiang Chang, Hsinchu Hsieh (TW)

(73) Assignee: INDUSTRIAL TECHNOLOGY RESEARCH INSTITUTE, Hsinchu Hsien (TW)

(21) Appl. No.: 13/032,589

(22) Filed: Feb. 22, 2011

Related U.S. Application Data
(63) Continuation-in-part of application No. 11/616,260, filed on Dec. 26, 2006, now abandoned.

(30) Foreign Application Priority Data
Dec. 27, 2005 (TW) 94146633
Sep. 26, 2006 (TW) 95135707

(51) Int. Cl. B32B 3/00; B05D 5/02; B05D 5/00; C23C 16/34; C23C 16/50; C23C 4/04; C23C 4/12; B32B 7/02; B82Y 30/00; B82Y 40/00

(52) U.S. Cl. 428/141; 427/569; 427/452; 428/217; 977/891

(57) ABSTRACT

A hard water-repellent structure and a method for fabricating the same are provided. The method adopts an atmospheric pressure plasma deposition (APPD) technique to form a hard coating having a rough surface on a substrate, and form a water-repellent coating on the rough surface. Because the hard water-repellent structure includes the hard coating and the water-repellent coating, hardness, abrasion-resistance, transparency and hydrophobicity of the hard water-repellent structure are improved. The hard water-repellent structure protects the substrate from friction. Moreover, because the disclosure adopts the APPD technique to form the hard water-repellent structure, the cost of production is reduced dramatically. Thus, the disclosure can solve drawbacks of prior art.

### CROSS-REFERENCE TO RELATED APPLICATIONS

This application is a Continuation in part of the pending U.S. patent application Ser. No. 11/616,260 filed on Dec. 26, 2006, which claims foreign priority 94146633 filed on Dec. 27, 2005 and foreign priority 95135707 filed on Sep. 26, 2006, all of which is hereby incorporated by reference in its entirety.

Although incorporated by reference in its entirety, no arguments or disclaimers made in the parent application apply to this divisional application. Any disclaimer that may have occurred during the prosecution of the above-referenced application(s) is hereby expressly rescinded. Consequently, the Patent Office is asked to review the new set of claims in view of the entire prior art of record and any search that the Office deems appropriate.

### TECHNICAL FIELD

The disclosure relates to substrate surface modification techniques, and more particularly, to a hard water-repellent structure and a method for fabricating the same by an atmospheric pressure plasma deposition technique.

### BACKGROUND

Owing to the ever-growing demands for slim and miniaturized commodity products in recent years, a variety of industries have been intersecting with nanotechnology to create new products that undergo changes in their physical properties. The products with such physical changes have developed new functions or uses to meet the needs of industry or individual consumer. For instance, recent commodity products are often integrated with self-cleaning systems, which can reduce maintenance cost and increase quality of the products, thus market demand for those products increases dramatically. As a result, self-cleaning coating materials, which are low cost self-cleaning systems, have received a great public attention and become extremely popular over the past few years due to the foregoing reasons.

Self-cleaning coating materials are applicable to a wide range of applications. For instance, coating or depositing self-cleaning materials on glasses fitted in buildings or surfaces of kitchens and bathroom can reduce maintenance cost; coating or depositing self-cleaning water-repellent materials on surfaces of solar cells, satellites, or windshield of car can improve quality and performance of the products; and coating or depositing self-cleaning materials on external surfaces of transport vessels (such as boats/ships or aircrafts) can reduce fuel consumption due to resistance force, and therefore reduce air pollution. Studies of self-cleaning coating materials suggest that properties of lotus effect provided by having air particles captured within a rough surface to form a sort of air-cushion are combined with surface properties of low surface energy material to make a water contact angle on a coating material larger than 100°, so as to reduce the possibility of coherence of water or oil.

Structure of the prior-art self-cleaning coating materials is usually designed as a multi-layered complex structure to fulfill hydrophobic and self-cleaning functions. The multi-layered structure is adhesive, and has a rough surface with low surface energy; however such hard water-repellent structure has a poor adhesion, insufficient hardness, low transparency and inferior abrasion-resistance, due to inferior structural properties and designs caused by conventional fabrication techniques.

A conventional way to form the prior-art water-repellent structure on a surface of the substrate can be done via conducting a Wet Process by preparing a water-repellent solution for fabrication, or a Dry Process by applying vacuum-plasma deposition.

To fabricate the water-repellent structure by the use of the water-repellent solution is a conventional fabrication technique the includes the following three steps, preparing a solution containing water-repellent materials, spraying the water-repellent materials on the surface of the substrate, and curing of post-manufacturing process. Generally, the shortest period necessary for fabricating the water-repellent materials is about 1-2 days; however, such fabrication time may be extended to 5-7 days, or even longer. Fabrication method as such is time-consuming and requires expensive equipments, thereby increasing the cost of production. Further, the water-repellent structure manufactured via the foregoing fabrication method is really fragile and too rough, thereby providing poor abrasion-resistance and durability, as well as lowering the transparency of the depositing layer (coating). The properties of the water-repellent structure and the stability of the solution may also be varied easily, thus the foregoing technique is not an ideal method and feasible practical implementation for fabricating the water-repellent. Moreover, after the solution of water-repellent materials is applied on the substrate, a further processing step, curing, has to be performed through lighting or heating. Despite the extra cost for equipping costly spraying and heating devices, to prepare spaces for these enormous equipments would be very cost-inefficient.

Referring to the following prior arts, U.S. Pat. No. 5,230,929, U.S. Pat. No. 5,298,587, U.S. Pat. No. 5,320,857, U.S. Pat. No. 5,718,967, and U.S. Pat. No. 6,667,553, a technique, vacuum-plasma deposition, for fabricating a coating on a substrate is disclosed. However, most of the coatings fabricated by the vacuum-plasma deposition technique have a poor hydrophobicity and hardness. Among these coatings, only a few of them can obtain a pencil hardness of 9H, but such fabrication process is hard to control and often results in undesired thickness variations that may decrease transparency. Further, the vacuuming process is very time-consuming, and the spraying area is often limited by the use of the spraying equipment, making the fabrication method as such unable to be applied to any application requiring the water-repellent materials to be sprayed over a large surface area.

Referring to the disclosures of U.S. Pat. No. 5,230,929 and U.S. Pat. No. 5,334,454, fluorinated cyclic siloxanes is used as an essential material to form a coating via chemical vapor deposition (CVD) at a pressure of 0.1 Torr by performing vacuum plasma spraying technique, wherein the coating has a water contact angel of 91°, a pencil hardness of 9H, and a thickness of the coating of 1˜2 μm. Nevertheless, the fabrication method involving vacuum deposition is time-consuming, elaborated, costly, and the structure thereof is opaque and barely water resistant.

Referring to the disclosures of U.S. Pat. No. 5,298,587, U.S. Pat. No. 5,320,857, and U.S. Pat. No. 5,718,967, SiOₓC_{y} H_{z}, such as tetramethyldisiloxane, is deposited on a polycarbonate substrate via vacuum plasma evaporation at a temperature of 27 mTorr; however, the fabrication method involving vacuum deposition is time-consuming, elaborated, costly, and the structure thereof has a low hardness and hydrophobicity.

Referring to the disclosure of U.S. Pat. No. 6,667,553, trimethysilane is deposited on a silicon substrate via CVD at a pressure lower than 5 Torr and a controlled oxygen concentration during fabrication, wherein the thickness of the coating is less than 2 μm, and the transparency thereof is higher than 95%. The foregoing fabrication is mainly applied to display devices; however, it is time-consuming, elaborated, costly due to vacuum deposition, as stated above.

A coating modifying a surface on a substrate can be deposited using plasma CVD under various pressures inclusive of sub-atmospheric to atmospheric pressure, e.g., Plasma Enhanced CVD (PECVD), as disclosed in U.S. Patent Application 2002/0172939. U.S. Pat. No. 5,733,610 proposes a technique, in order to overcome the aforementioned drawbacks in the prior art, using atmospheric pressure plasma (APP) reaction to form a coating of a water-repellent film. Such fabrication technique, employing tetrafluorocarbon as a reactive gas and depositing tetrafluorocarbon on a surface of polyethylene terephthalate (PET) substrate directly, is performed to form the water-repellent film with a highest water-contact angle of 98°. Because the highest water-contact angle of the water-repellent film is only 98°, the water-repellent film can only provide an insufficient hydrophobicity, a low hardness, and a poor abrasion-resistance, making it unable to protect the substrate.

Referring the disclosure of U.S. Patent Publication No. 2004/0022945 discloses a technique, depositing CF₃(CF₂)₅CH═CH₂ (1H, 1H, 2H-Perfluoro-1-octene) monomer on a glass substrate via atmospheric pressure plasma deposition to form a coating (depositing layer), which exhibits a water contact angle of 119°. However, such coating is formed with low hardness and poor abrasion-resistance, and therefore it cannot be used to provide protection for the substrate. Generally, as discussed above, coatings fabricated by low pressure or vacuum deposition techniques have low hydrophobicity. Further, only a few of them can obtain a pencil hardness of 9H, but the fabrication method as such is difficult to control and often results in undesired thickness variations that may scarify transparency of the coatings. The vacuuming process involved in the fabrication is very time-consuming and the spraying area is often limited by the spraying equipment, therefore such fabrication method fails to meet the demand of the market as it is not applicable to any application with the need of spraying the water-repellent materials over a large surface area. As recited in the disclosures of the foregoing prior arts, atmospheric pressure plasma is used for deposition via a dry process to save deposition time, spaced occupied by the equipments, and cost of production, and the prior-art coatings fabricated by atmospheric pressure plasma deposition techniques are hydrophobic and have different water-contact angles; however such coatings lack of sufficient hardness and abrasion-resistance, making it unable to protect the substrate.

In this regard, a need still remains for providing a water-repellent structure that can provide sufficient hardness, hydrophobicity, and abrasion-resistance. Solutions to these problems have been long sought but prior developments have not taught or suggested any satisfactory solutions and, thus, solutions to these problems have long eluded those ordinarily skilled in the art.

### SUMMARY

The disclosure proposes a hard water-repellent structure, which is formed on a surface of a substrate by atmospheric pressure plasma deposition (APPD) technique. The hard water-repellent structure comprises a hard coating (depositing layer) and a water-repellent coating (depositing layer); the hard coating with a rough surface is formed on the surface of the substrate and the water-repellent coating is formed on the rough surface of the hard coating, in which the average roughness of the hard water-repellent structure ranges from 9 nm to 1 μm. In one embodiment, the average roughness of the hard water-repellent structure ranges from 9 nm to 0.5 μm, and the hard coating is harder than the water-repellent coating.

The thickness of the hard coating ranges from 20 nm to 5 μm (e.g., 20 nm to 3 μm). In one embodiment, the hard coating may be a metal-oxide coating, nitride coating or its derivatives. The metal oxide coating may be made of at least one material selected from the group consisting of silicon oxide, titanium dioxide, zirconium dioxide and aluminum oxide. The nitrides and derivatives are made of silicon nitride (e.g., SiNx, Si3N4), titanium nitride (e.g., TiNx), or tantalum nitride (e.g., TaNx). The thickness of the water-repellent coating ranges from 5 nm to 3 μm (e.g., 10 nm to 0.5 nm). In one embodiment, the water-repellent coating may be a coating containing fluorine compound.

Further, the surface of the substrate is pretreated by an activation process, such that the surface of the substrate is cleaned and activated. In one preferred embodiment, the substrate may be made of at least one material selected from the group consisting of glass, metal, ceramic, rubber, plastic, polycarbonate (PC), polyethylene terephthalate (PET) and polymethylmethacrylate (PMMA).

The disclosure also purposes a method for fabricating the hard water-repellent structure, the method comprising the steps of: forming a hard water-repellent structure on a surface of the substrate by an atmospheric pressure plasma deposition (APPD) technique comprising the steps of: forming the hard coating having a rough surface on the surface of the substrate; and forming the water-repellent coating on the rough surface such that the hard water-repellent structure formed on the surface of the substrate is composed of the hard coating and the water-repellent coating, wherein the average roughness of the rough surface of the hard coating ranges from 9 nm to 1 μm, and the hard coating is harder than the water-repellent coating.

Further, before forming the hard coating on the surface of the substrate, the surface of the substrate is pretreated by an activation process, so as to allow the surface of the substrate to be cleaned and activated. In one embodiment, during the activation process, the atmospheric pressure plasma generated by air or compressed dried air may clean and activate the surface of the substrate. In another embodiment, the substrate may be made of at least one material selected from the group consisting of glass, metal, ceramic, rubber, plastic, polycarbonate (PC), polyethylene terephthalate (PET) and polymethylmethacrylate (PMMA).

The thickness of the hard coating ranges from 20 nm to 5 μm (e.g., 20 nm to 3 μm). In one embodiment, the hard coating may be a metal-oxide coating, wherein the metal-oxide coating may be made of at least one material selected from the group consisting of silicon oxide, silicon nitride, titanium dioxide, zirconium dioxide and aluminum oxide. The water-repellent coating ranges from 5 nm to 3 μm in thickness (e.g., 10 nm to 0.5 μm). In one embodiment, the water-repellent coating may be a coating containing fluorine compound.

Furthermore, the APPD technique in accordance with the disclosure is performed to generate plasma for plasma spray coating by feeding a gas mixture through a nozzle under pressure and temperature control. The pressure may ranges from 1 to 760 Tons, and the gas mixture may comprise at least a feeding gas and at least a precursor. In one embodiment, the gas mixture may be at least one material selected from the group consisting of fluoroalkyl group-containing trichlorosilanes, fluoroalkyl group-containing trialkoxysilanes, fluoroalkyl group-containing triacyloxysilanes, fluoroalkyl group-containing tri-isocyanatesilanes and fluoroalkyl group-containing acrylatesilanes.

Comparing with the prior art, the disclosure provides, using APPD technique, a hard water-repellent structure which has a hard coating having a rough surface on a substrate and a water-repellent coating on the rough surface in sequence, and a method for fabricating the hard water-repellent structure to form, so as to improve the hardness and abrasion-resistance of the hard water-repellent structure, such that the substrate can be well protected by the hard water-repellent structure. The design of the disclosure can reduce the thickness of the hard water-repellent structure, such that the hard water-repellent structure of the disclosure can be fabricated with a higher transparency than the prior art. In addition, the design of the roughness of the hard coating of the disclosure can increase hydrophobicity of the hard water-repellent structure, thereby enhancing the effect of water-resistance.

Moreover, unlike the use of vacuum-plasma deposition technique in the prior art, the use of APPD technique in the disclosure may save time for vacuuming air out of equipments, reduce spaces occupied by enormous and numerous equipments and simply coating processes, thereby allowing the disclosure to be integrated into any existing production line, as well as reducing the cost of production dramatically. Accordingly, the disclosure not only solves drawbacks of the prior art, but also provides processes and configurations for read, efficient, and economical manufacturing, application, and utilization.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF DRAWINGS

FIG. 1 is a schematic cross-sectional view of a hard water-repellent structure according to an embodiment of the disclosure;

FIGS. 2A to 2C are schematic cross-sectional views showing procedural steps of a method for fabricating a hard water-repellent structure according to an embodiment of the disclosure;

FIG. 3A is an Atomic Force Microscope image of a hard water-repellent structure according to an embodiment of the disclosure;

FIG. 3B is a Roughness Chart of a hard water-repellent structure according to the embodiment of the disclosure;

FIG. 3C is a photograph showing a water contact angle test of a water droplet on a hard water-repellent structure according to the embodiment of the disclosure;

FIG. 4A is an Atomic Force Microscope image of a hard water-repellent structure according to another embodiment of the disclosure;

FIG. 4B is a Roughness Chart of a hard water-repellent structure according to another embodiment of the disclosure; and

FIG. 4C is a photograph showing a water contact angle test of a water droplet on a hard water-repellent structure according to another embodiment of the disclosure.

### DETAILED DESCRIPTION OF THE INVENTION

The following embodiments are described in sufficient detail to enable those skilled in the art to make and use the invention. It is to be understood that other embodiments would be evident based on the present disclosure, and that proves or mechanical changes may be made without departing from the scope of the disclosure.

In the following description, numerous specific details are given to provide a thorough understanding of the invention. However, it will be apparent that the disclosure may be practiced without these or other specific details known in the art. In order to avoid obscuring the disclosure, some well-known details in configurations and process steps are still not disclosed here.

Likewise, the drawings showing embodiments of the structure are semi-diagrammatic and not to scale and, particularly, some of the dimensions are for the clarity of presentation and are shown greatly exaggerated in the drawings. Similarly, although the views in the drawings for ease of description generally show similar orientations, this depiction in the drawings is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane. Generally, the term “hard” means a material with a hardness above the pencil hardness 3H, but no lower than 1H. The term “harder” refers to a larger hardness for one material than another. Importantly, the term “average roughness (Ra)” refers to the arithmetic average of the absolute values of the roughness profile ordinates, also known as Arithmetic Average (AA), Center Line Average (CLA). The term “maximum roughness depth (Rmax)” refers to the vertical distance between the highest peak and the lowest valley of the roughness profile of a surface.

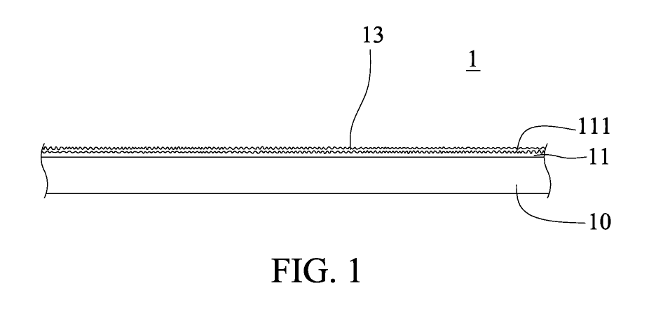

FIG. 1 is a schematic cross-sectional view of a hard water-repellent structure 1 of an embodiment according to the disclosure. The hard water-repellent structure 1 is formed on a surface of a substrate 10 by an atmospheric pressure plasma deposition (APPD) technique. The hard water-repellent structure 1 comprises a hard coating 11 and a water-repellent coating 13. The hard coating 11 is formed on the surface of the substrate 10 and has a rough surface 111. The water-repellent coating 13 is formed on the rough surface 111. The average roughness (Ra) of the surface of the hard water-repellent structure 1 ranges from 9 nm to 1 μm. In one embodiment, the average roughness of the surface of the hard water-repellent structure 1 ranges from 9 nm to 0.5 μm. On the other hand, in the water-repellent structure the hard coating 11 is harder than the water-repellent coating 13, so as to provide sufficient protection to the underlying substrate.

In addition to providing sufficient hardness of protecting the underlying substrate, the hard water-repellent structure 1, which includes the hard coating 11 and the rough surface 111 and thus has the Ra ranging from 9 nm to 1 μm, exhibits also a contact angle (water contact angle) way above an angle of 100 degree. As a result, the hard water-repellent structure 1 has an increased hydrophobicity. It is noteworthy that, unlike some of the prior art in which a surface roughness is modified to obtain a smooth surface as well as an adequate adhesion for a subsequent coating, the embodiment features a specific Ra exhibiting a significant improvement in hydrophobicity and hardness of the hard water-repellent structure, regardless of the effects on the adhesion to subsequent coatings. For example, in US2005/0271893, it is required that the minimum root mean square (RMS) surface roughness is greater than or about 4 nm to provide adequate adhesion for the subsequently deposited hydrophobic coatings, but at the same time the RMS surface roughness should be 6.0 nm or less for retaining smoothness.

On the other hand, because the hard water-repellent structure 1 formed on the surface of the substrate 10 by the APPD technique, and the APPD technique has a low operation temperature and is called low-temperature plasma or cold plasma, substrate 10 can be made of varieties of materials, such as glass, metal, ceramic, rubber, plastic, polycarbonate (PC), polyethylene terephthalate (PET) and polymethylmethacrylate (PMMA). Further, the surface of the substrate 10 is pretreated by an activation process, such that the surface of the substrate 10 is cleaned and activated.

According to an embodiment, the hard coating 11 is a silicon-dioxide coating, and has a thickness between 20 and 5 μm, and the rough surface 111 has an average roughness which ranges from 9 nm to 1 μm. Further, the water-repellent coating 13 is a coating containing fluorine compound. The water-repellent coating 13 has a thickness between 5 nm to 3 μm. Although a specific range of the thickness of the hard coating 11 and that of the water-repellent coating 13 are described as above, it is to be noted that such ranges may vary and are not limited to that described. For instance, the hard coating 11 is made of any metal-oxide coating material, nitride coating or its derivatives. The metal-oxide coating is one selected from the group consisting of silicon oxide, titanium dioxide, zirconium dioxide and aluminum oxide. The nitride coating and its derivatives are made of silicon nitride (e.g., SiNx, Si3N4), titanium nitride (e.g., TiNx), or tantalum nitride (e.g., TaNx).

Because the hard water-repellent structure 1 of the disclosure comprises the water-repellent coating 13, and the hard coating 11 which is harder than the water-repellent coating 13, the hardness and abrasion-resistance of the hard water-repellent structure 1 are improved, such the water-repellent substrate 1 protecting the substrate 10 from friction. Further, since the design of the disclosure can reduce the thickness of the hard water-repellent structure 1, the hard water-repellent structure 1 according to the disclosure can be fabricated with a higher transparency than the prior art.

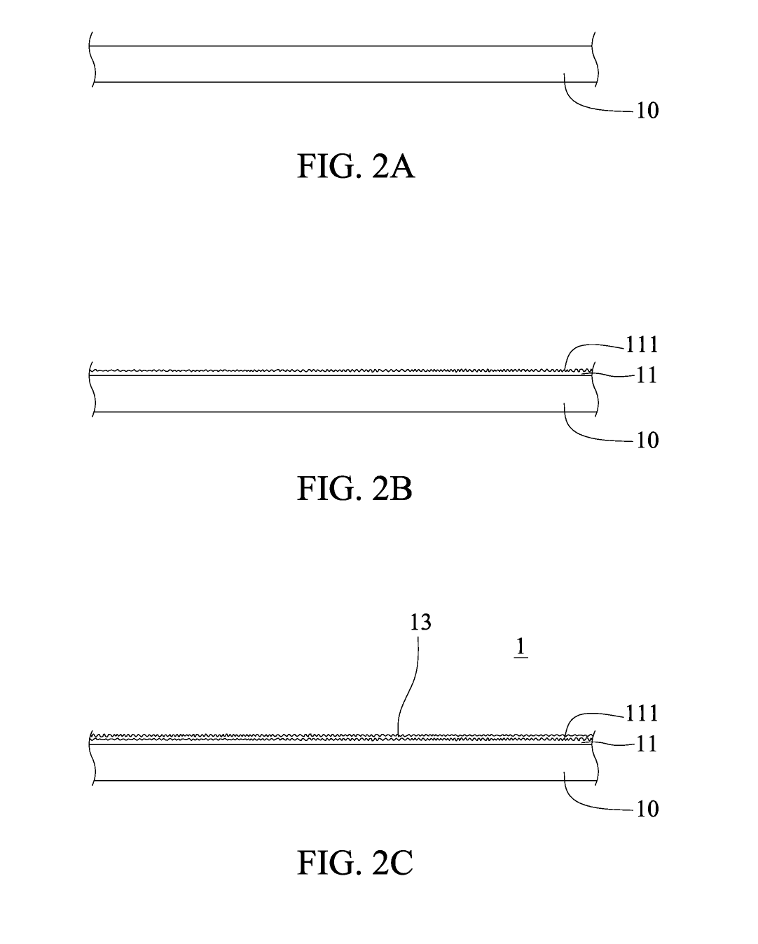

FIGS. 2A to 2C are schematic cross-sectional views showing procedural steps of a method for fabricating the hard water-repellent structure 1 according to the disclosure. An Atmospheric Pressure Plasma Jet produced by Plasma Treat Inc. in Germany (as shown in the disclosure of U.S. Pat. No. 6,800,336) serving as a piece of demonstration equipments is used, in conjunction with a two-dimensional or three-dimensional spraying device, a material storing/releasing device connected to the Atmospheric Pressure Plasma Jet, and a control device for controlling the operations of the spraying device and the material storing/releasing device, as an example to demonstrate the method.

As shown in FIG. 2A, the method includes providing the substrate 10, which has a surface cleaned and activated by compressed dry air (CDA). The amount of CDA flow is about two cube meters per hour, and the distance between a nozzle of the Atmospheric Pressure Plasma Jet and the surface of the substrate 10 is maintained at about 10 mm Then, the process treating the substrate 10 with CDA is repeated twice. In one embodiment, the substrate 10 is made of glass; however, in another embodiment, the substrate 10 may be made of a material selected from the group containing metal, ceramic, rubber, plastic, polycarbonate (PC), polyethylene terephthalate (PET) and polymethylmethacrylate (PMMA).

As shown in FIG. 2B, the method further includes forming the hard coating 11 having the rough surface 111 on the surface of the substrate 10 by the APPD technique. Helium (He), which is served as a carrier, and tetraethoxysilane (TEOS), as a precursor, are introduced into the equipments to generate plasma, and subsequently, a plasma spraying process is performed directly. The distance between the nozzle of the Atmospheric Pressure Plasma Jet and the surface of the substrate 10 is maintained at about 10 mm. Afterward, the process is repeated about twenty times.

As shown in FIG. 2C, the method further includes forming the water-repellent coating 13 on the rough surface 111 of the hard coating 11 by the APPD technique, wherein the hard coating 11 is harder than the water-repellent coating 13; in other words, the hard coating 11 has a higher hardness than that of the water-repellent coating 13. Therefore, the hard water-repellent structure 1 comprising the hard coating 11 and the water-repellent coating 13 is formed on the surface of the substrate 10, in which the hard water-repellant structure has an average roughness resulting from the rough surface 111 of the hard coating 11 and the water-repellant coating 13 ranging from 10 nm to 1 μm. In this step, helium (He), which is served as a carrier, and heptadecafluorodecyltrimethoxysilane (FAS), as a precursor, are introduced into the equipments to generate plasma, and subsequently a plasma spraying process is performed directly. The distance between the nozzle of the Atmospheric Pressure Plasma Jet and the surface of the substrate 10 is maintained at about 12 mm. Then, the process is repeated about six times.

Although, FAS is used as a precursor in the embodiment, it is noted that hexamethyldisilazane (HMDS) may be used as a precursor in another embodiment. Further, a gas mixture of the precursor and the carrier may be a material selected from the group consisting of fluoroalkyl group-containing trichlorosilanes, fluoroalkyl group-containing trialkoxysilanes, fluoroalkyl group-containing triacyloxysilanes, fluoroalkyl group-containing tri-isocyanatesilanes and fluoroalkyl group-containing acrylatesilanes.

### Experiment 1

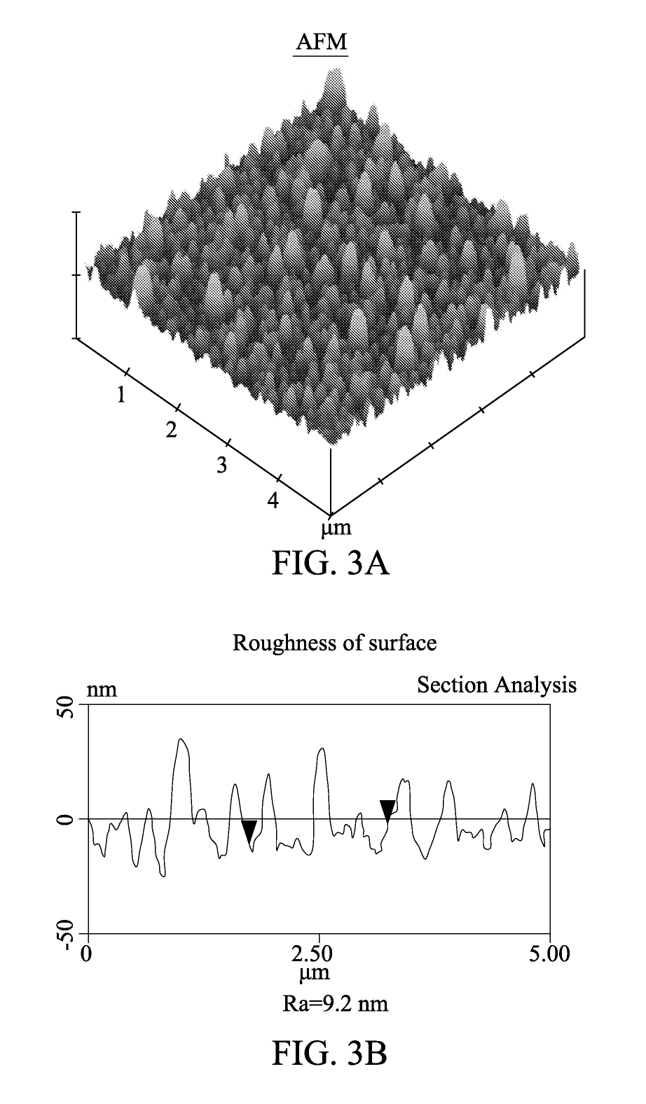

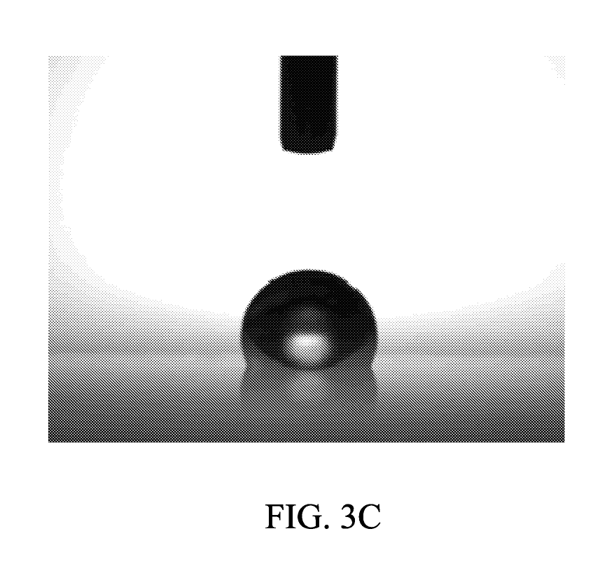

FIG. 3A is an Atomic Force Microscope image of the hard water-repellent structure 1 of an embodiment according the disclosure. FIG. 3B is a roughness chart of the hard water-repellent structure 1 of the embodiment. FIG. 3C is a photograph for a water contact angle test of the hard water-repellent structure 1 of the embodiment showing the water contact angle of the water with the hard water-repellent structure 1. After the water-repellent coating 13 is formed on the hard coating 11, the hard water-repellent structure 1 is formed. Referring to FIG. 3B, according to the embodiment the hard water-repellent structure 1 (a surface of the water-repellent coating 13) as shown in FIG. 1 had a central line average surface roughness (Ra) of about 9.2 nm and a maximum roughness depth (Rmax) of about 59.8 nm The water contact angle test of FIG. 3C exhibited a water contact angle of 115°. It is noted that the water contact angle of the water droplet on the hard water-repellent structure 1 maintained at 115° after the first seven days of the water contact angle test. Moreover, the hard water-repellent structure 1 of the embodiment according to the disclosure also enhances a number of other properties. For instance, the hard water-repellent structure 1 showed an oil contact angle of 59°, a transparency of about 92%, a pencil hardness of 2H, an adhesion of 91/100, and an anti-abrasion angle of about 105°.

### Experiment 2

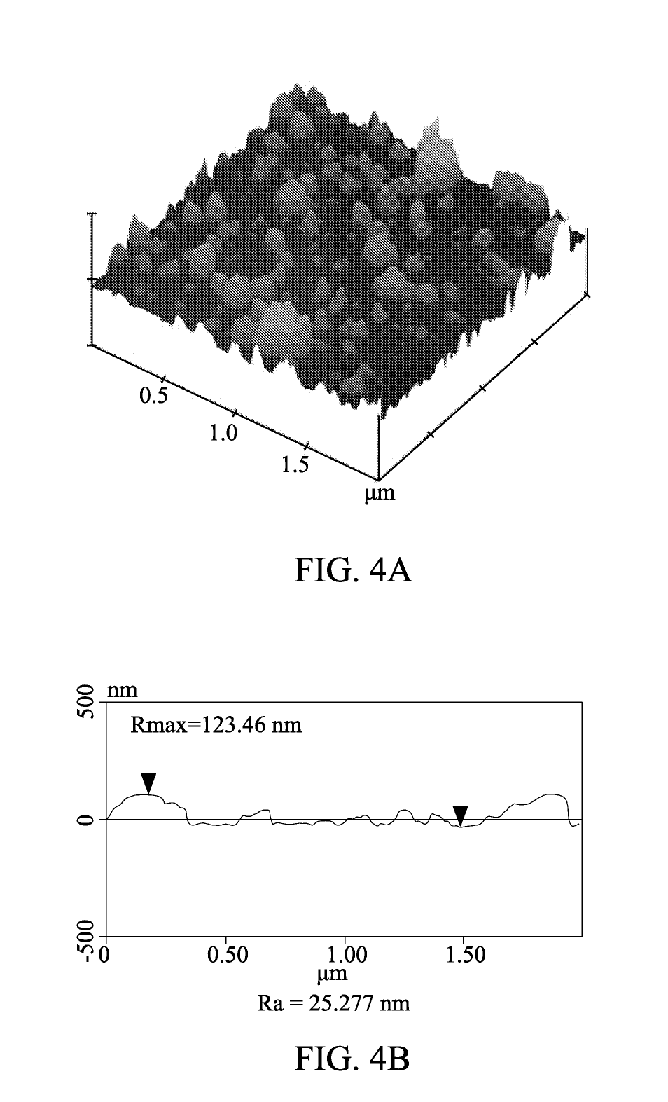

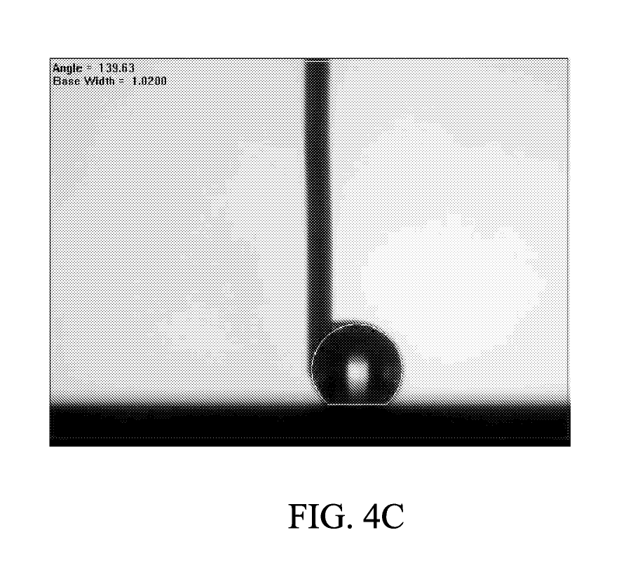

FIG. 4A is another Atomic Force Microscope image of the hard water-repellent structure 1 of another embodiment. FIG. 4B is roughness chart of the hard water-repellent structure 1 of another embodiment. FIG. 4C is a photograph for a water contact angle test of the hard water-repellent structure 1 of another embodiment, which illustrates the water contact angle of the hard water-repellent structure 1.

Referring to FIG. 4B, the surface of the hard water-repellent structure 1 (i.e., the surface of the water-repellent coating 13) as shown in FIG. 1 had an average roughness (Ra) of about 25.3 nm and a maximum roughness depth (Rmax) of about 123.5 nm FIG. 4C shows the experimental result of the water contact test that an water contact angle was 139°. Further, the water contact angle of the water droplet on the hard water-repellent structure 1 maintained at 139° after the first seven days of the water contact angle test.

Surprisingly, according to the Experiments 1 and 2 as well as further tests, it is found that when the maximum roughness depth (Rmax) of the surface of the hard water-repellent structure 1 is greater than 50 nm, the water contact angle significally increases and up to as high as 140°, and thus provides a further improved water resistant of the water-repelling structure with the substrate.

Details of measuring the properties of the hard water-repellent structure 1 are provided in the following descriptions.

### Water Contact Angle Test

The water contact angle test was conducted in accordance with American Society for Testing and Materials (ASTM) C 813-90, as follows:

1. A testing sample formed with a substrate and the hard water-repellent structure of the disclosure, was maintained in a horizontal plane level (the testing sample must be flat, not deformed, and not contaminated).
2. A micro-syringe was filled with de-ionized water/distilled water (as a testing fluid), and then a droplet of 2 μL of de-ionized water/distilled water was released from the micro-syringe. When the droplet was contacted with the surface of the testing sample, the tip of the syringe remained placed within the droplet was removed slowly (any traction or extensive movement of the syringe should be prevented, so as to avoid a change of the original volume/arriving position of the droplet).
3. The contact angle of the right side and the left side of the droplet were measured twice, and four measurements of the water contact angles were obtained.
4. Another four different locations on the same surface of the testing sample were tested for water contact angles by repeating the foregoing measuring procedures. Twenty measurements of the water contact angles were obtained, and subsequently, an average value of the water contact angle was calculated therefrom.

### Oil Contact Angle Test

The procedures for conducting the oil contact angle test are the same with that for the water contact angle test, except changing the testing fluid from de-ionized water/distilled water to hexadecane. The oil contact angle test was conducted, measurements were obtained and an average value of the oil contact angle was calculated therefrom.

### Pencil Hardness Test

The pencil hardness test was conducted in accordance with ASTM 3363-92a, as follows:

1. Environmental Conditions were set as follows: 23±2° C. air temperature and 50±5% relatively humidity.
2. A testing sample formed with a substrate and the hard water-repellent structure of the disclosure, was placed under such environmental conditions for 16 hours first.
3. Pencils with different hardness were prepared (6B-5B-4B-3B-2B-B-HB-F-H-2H-3H-4H-5H-6H-7H-8H-9H, ranging from the softest to the hardest).
4. An end of each pencil was cut into a sharp, flat, or oval end by a pencil sharpener to expose the lead of a pencil. Then, the exposed lead was flattened perpendicularly (90°) to the pencil axis by a sanding paper, such that the lead of the pencil (with a diameter of 5 to 6 mm) was flat, not damaged and not cracked.
5. The pencils were tested in order, according to the range of hardness. A pencil with the maximum hardness was tested first. The pencil was held by hands or an pushing device at a 45 degree angle to a surface of the testing sample, and pushed forward (away from the object holding the pencil) and pushed downward firmly (toward the object) using as much downward pressure as could be applied without breaking the lead of the pencil to make a mark with at least 6.5 mm long, at a pushing speed of 0.5˜1 mm/s With each try, the testing process should not be stopped until a pencil could not penetrate coatings and be contacted with the substrate; however, a pushing distance greater than 3 mm must be made before stopping the test process (a magnifying glass could be used to examine such distance). If the lead of a pencil is damaged during the testing process, the test must be restarted all over again.
6. When a pencil could no longer make any mark on the coatings, the hardness of the coatings was measured (i.e. the pencil that could not make any mark on the coatings has about the same hardness as the coatings).
7. The testing process was repeated at least once with the pencil having the same hardness as the coatings, until the same result was obtained.

### Transparency Test

The transparency test was conducted in accordance with ASTM D 1747-97, as follows:

1. A 50 mm×100 mm testing sample (A) formed with a substrate and the hard water-repellent structure of the disclosure, and a 50 mm×100 mm control testing sample (B) formed with a substrate and without the hard water-repellent structure, were prepared.
2. An ultraviolet (UV) irradiation device of CNS10986 was prepared.
3. Visible transmittance (%) of each testing sample was measured first using an integrating sphere to calculate its chromatic aberrations. After placing the testing sample (A) and the testing sample (B) (in the UV irradiation device) at a temperature of 45±5° C. and at a location 230 mm away from a light source (UV light), and exposing the testing samples to UV light for 1000 hours, visible transmittances (%) of the testing samples were measured again.
4. Transparency of the testing sample (A) was obtained by calculating difference of the visible transmittances (%) of the testing sample (A) before and after treated with UV light (i.e. an absolute value). Transparency of the testing sample (B) was also calculated for comparison.

### Adhesion Test

The adhesion test was conducted in accordance with ASTM D 3359-95, as follows:

1. Semi-transparent and pressure-sensitive adhesive tapes with a width of 25 mm were prepared. The adhesion of each tape was 10±1 N/25 mm
2. 150 mm×100 mm testing samples, having each of the testing samples being formed with a substrate and the hard water-repellent structure (coatings) of the disclosure, were prepared. Each testing sample was fixed on a platform (each testing substrate must be flat, not deformed, and not contaminated).
3. If a testing sample was formed with a soft/hard substrate having a thickness of the coatings smaller than 50 or 60 μm, a space between cutting marks (25 sections) was 1 mm; if a testing sample was formed with a soft/hard substrate having a thickness of the coatings between 50 or 60 μm-120 μm, a space between cutting marks (25 sections) was 2 mm; if a testing sample was formed with a soft/hard substrate having a thickness of the coatings larger than 120 μm-250 μm, a space between cutting marks (25 sections) was 3 mm.
4. It should be noted that if a testing sample was formed with a hard substrate, the coating must be larger than 0.25 mm; if a testing sample was formed with a soft substrate, the coating must be larger than 10 mm.
5. A scraper with a width of 0.05 mm was prepared; however the scraper must be re-sharpened, if the scraper had a width larger than 0.1 mm.
6. Environmental Conditions were set as follows: 23±2° Cair temperature and 50±5% relatively humidity.
7. The testing sample was cut twice perpendicularly, with sufficient and constant force, to its substrate with each cutting length larger than 20 mm by using the scraper that was held at a 45 degree angle to the surface of the testing sample. After cutting, the testing sample was wiped softly by a cotton cloth or soft brush, and then the tape was firmly attached to the testing sample by hands. Subsequently, the tape was remove at a 180 degree angle to the surface of the testing sample at a removing speed of 0.5-1 mm/s. (An external light source or magnifying glass could be used for examination; however any appendant stuck on the tape could also be viewed as a reference.)
8. The water contact angles on the testing sample before and after the adhesion test were measure. If the water contact angles were 100° before the test and 90° before the test, the adhesion strength of the testing sample would be 90/100. (The strongest adhesion strength would be 100/100, and the weakest adhesion strength would be 0/100.)
9. Another three locations of the testing sample were tested, wherein any one of the locations was spaced at least 5 mm from the others and at least 5 mm from the edge of the testing sample. Then, an average value of the adhesion strength was calculated from the results of the adhesion tests of these locations.

According to the foregoing embodiments and experiments, atmospheric pressure plasma deposition (APPD) technique of the disclosure is a dry process of plasma spraying, depositing the water-repellent materials on the surface of the substrate directly, thereby saving a lot of time and spaces required for fabrication equipments. Moreover, unlike the use of vacuum-plasma deposition technique in the prior art, the use of APPD technique in the disclosure may save time for vacuuming air out of equipments, reduce spaces occupied by enormous and numerous equipments and simply coating processes, thereby allowing the disclosure to be integrated into any existing production line. As a result, a more advanced and valuable product is fabricated with a much lower cost of production. Furthermore, as atmospheric pressure plasma is used under a low temperature condition, substrates can be made of heat-resistance materials such as glass, ceramic or metal, or plastic materials such as polycarbonate (PC), polyethylene terephthalate (PET), polymethylmethacrylate (PMMA), Polyimide (PI), Polyurethane (PU), or Triallyl cyanurate (TAC). The use of plastic materials allows the disclosure to be manufactured in a speedy, continuous, easy and simple way, and applicable to any substrate with 3D curved-surfaces or large surface areas. Due to the aforementioned advantages, the disclosure is applicable to a wide range of commercial and industrial applications (i.e. Computing, Communications and Consumer electronics products, commodity products, biotechnology products, and industrial products), and can be integrated into any existing production line.

Comparing with the prior art, the disclosure provides a hard water-repellent structure and a method for fabricating the same, using APPD technique to form a hard coating having a rough surface on a substrate and a water-repellent coating on the rough surface in sequence, so as to improve the hardness and abrasion-resistance of the hard water-repellent structure, such that the substrate can be well protected by the hard water-repellent structure. The design of the disclosure can reduce the thickness of the hard water-repellent structure, such that the hard water-repellent structure of the disclosure can be fabricated with a higher transparency than the prior art. In addition, the design of the roughness of the hard coating of the disclosure can increase hydrophobicity of the hard water-repellent structure, thereby enhancing the effect of water-resistance. Moreover, the use of APPD technique in the disclosure saves time for vacuuming air out of equipments, reduces spaces occupied by enormous and numerous equipments and simply coating processes, thereby allowing the disclosure to be integrated into any existing production line, as well as reducing the cost of production dramatically. Accordingly, the disclosure not only solves drawbacks of the prior art, but also provides processes and configurations for read, efficient, and economical manufacturing, application, and utilization.

While the disclosure has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters hithertofore set forth herein or shown in the accompanying drawings are to be interpreted in an illustrative and non-limiting sense.

What is claimed is:

1. A method for fabricating a hard water-repellent structure, the method comprising the steps of:
providing a substrate;
forming a hard water-repellent structure on a surface of the substrate by an atmospheric pressure plasma deposition (APPD) technique comprising the steps of:
forming a hard coating having a rough surface on the surface of the substrate; and
forming a water-repellent coating on the rough surface, such that the water-repellent structure formed on the surface of the substrate is composed of the hard coating and the water-repellent coating,
wherein the hard water-repellent structure has an average roughness ranging from 9 nm to 1 μm and the hard coating is harder than the water-repellent coating.

2. The method of claim 1, wherein the hard water-repellent structure has an average roughness ranging from 9 nm to 0.5 μm.

3. The method of claim 1, wherein the hard water-repellent structure further has a maximum roughness depth no smaller than 50 nm.

4. The method of claim 1, wherein the surface of the substrate is pretreated by an activation process.

5. The method of claim 1, wherein the hard coating has a thickness between 20 nm to 5 μm.

6. The method of claim 1, wherein the water-repellent coating has a thickness between 5 nm and 3 μm.

7. The method of claim 6, wherein the water-repellent coating has a thickness between 10 nm to 0.5 μm.

8. The method of claim 1, wherein the hard coating is a metal-oxide coating.

9. The method of claim 1, wherein the hard coating is the nitride coating, and the nitride coating comprises at least one selected from the group consisting of silicon nitride, titanium nitride, and tantalum nitride.

10. The method of claim 1, wherein the water-repellent coating comprises fluorine compound.

11. The method of claim 1, wherein the APPD technique is performed to generate plasma for plasma spray coating by feeding a gas mixture comprising at least a feeding gas and at least a precursor through a nozzle under pressure and temperature control, in which the precursor comprises at least one selected from the group consisting of fluoroalkyl group-containing trichlorosilanes, fluoroalkyl group-containing trialkoxysilanes, fluoroalkyl group-containing triacyloxysilanes, fluoroalkyl group-containing tri-isocyanatesilanes and fluoroalkyl group-containing acrylatesilanes.

12. The method of claim 11, wherein the pressure is between 1 and 760 Torr.

13. A hard water-repellent structure, which is formed on a surface of a substrate, the hard water-repellent structure comprising:
a hard coating formed on the surface of the substrate and having a rough surface, and
a water-repellent coating formed on the rough surface of the hard coating, wherein the average roughness of the rough surface ranges from 9 nm to 1 μm and the hard coating is harder than the water-repellent coating.

14. The hard water-repellent structure of claim 13, wherein the hard water-repellent structure has an average roughness ranging from 9 nm to 0.5 μm.

15. The hard water-repellent structure of claim 13, wherein the hard water-repellent structure further has a maximum roughness depth no smaller than 50 nm.

16. The hard water-repellent structure of claim 13, wherein the hard coating has a thickness between 20 and 5 μm.

17. The hard water-repellent structure of claim 13, wherein the hard coating is a metal-oxide coating.

18. The hard water-repellent structure of claim 17, wherein the metal-oxide coating comprises at least one selected from the group consisting of titanium dioxide, zirconium dioxide and aluminum oxide.

19. The hard water-repellent structure of claim 13, wherein the hard coating is the nitride coating, and the nitride coating comprises at least one selected from the group consisting of silicon nitride, titanium nitride, and tantalum nitride.

20. The hard water-repellent structure of claim 13, wherein the water-repellent coating has a thickness between 5 to 3 μm.

21. The method of claim 13, wherein the water-repellent coating has a thickness between 10 nm to 0.5 μm.

22. The hard water-repellent structure of claim 13, wherein the water-repellent coating comprises fluorine compound.

22. The hard water-repellent structure of claim 13, wherein the substrate comprises at least one selected from the group consisting of glass, metal, ceramic, rubber, and plastic.
